(19) United States
(12) Patent Application Publication
(10) Pub. No.: US 2024/0404907 A1
(43) Pub. Date: Dec. 5, 2024

(54) ELECTRONIC DEVICE PROTECTION STRUCTURE, CIRCUIT BOARD, DISPLAY MODULE AND MANUFACTURING METHOD

(71) Applicants: Chengdu BOE Optoelectronics Technology Co., Ltd., Chengdu, Sichuan (CN); BOE Technology Group Co., Ltd., Beijing (CN)

(72) Inventors: Yangyang CAI, Beijing (CN); Ying ZHANG, Beijing (CN); Zhihao XIE, Beijing (CN); Hengzhen LIANG, Beijing (CN)

(21) Appl. No.: 18/701,837

(22) PCT Filed: Apr. 21, 2023
(86) PCT No.: PCT/CN2023/089684

§ 371 Date: Apr. 16, 2024

(30) Foreign Application Priority Data
May 24, 2022 (CN) 202210569922.9

(51) Int. Cl. H01L 23/31; H01L 23/498

(52) U.S. Cl. CPC H01L 23/3171; H01L 23/49838

(57) ABSTRACT

An electronic device protection structure includes: a substrate, a component group on a side of the substrate, a first protective adhesive tape on a side of the component group away from the substrate, and a second protective adhesive tape on a side of the first protective adhesive tape away from the component group. The first protective adhesive tape includes a covering portion covering the component group, and a lapping portion extending from at least one side of the covering portion until the lapping portion comes into contact with the substrate. The second protective adhesive tape is attached to the periphery of the component group, and is electrically connected to the lapping portion.

### CROSS-REFERENCE TO RELATED APPLICATION

The present disclosure is a National Stage of International Application No. PCT/CN2023/089684 filed Apr. 21, 2023, which claims priority to Chinese patent application No. 202210569922.9, filed with the China National Intellectual Property Administration (CNIPA) on May 24, 2022, and entitled “ELECTRONIC DEVICE PROTECTION STRUCTURE, CIRCUIT BOARD, DISPLAY MODULE AND MANUFACTURING METHOD”, the entire contents of which are incorporated herein by reference.

### TECHNICAL FIELD

The present disclosure relates to the technical field of semiconductors, in particular to an electronic device protection structure, a circuit board, a display module and a manufacturing method.

### BACKGROUND

Since a foldable cell phone has the folding characteristic, a gap exists between a whole screen and a middle frame. The waterproof function cannot be achieved through a shell, and thus the waterproof performance of a foldable product is not good. In the related art, the use of spot coating of waterproof adhesives usually causes the problem of deterioration of the electrostatic shielding effect of a protective adhesive tape.

### SUMMARY

The present disclosure provides an electronic device protection structure, a circuit board, a display module and a manufacturing method.

Embodiments of the present disclosure provide an electronic device protection structure, including: a substrate, a component group located on a side of the substrate, a first protective adhesive tape located on a side of the component group away from the substrate, and a second protective adhesive tape located on a side of the first protective adhesive tape away from the component group.

The first protective adhesive tape includes: a covering portion covering the component group, and a lapping portion extending from at least one side of the covering portion until the lapping portion comes into contact with the substrate.

The second protective adhesive tape is attached to a periphery of the component group, and is electrically connected to the lapping portion.

In a possible implementation, a gap is provided between the second protective adhesive tape and the component group.

In a possible implementation, the lapping portion includes: a first lapping portion and a second lapping portion connecting the first lapping portion to the covering portion.

The first lapping portion is in contact with the substrate, and the lapping portion is electrically connected to the second protective adhesive tape at the first lapping portion.

In a possible implementation, the first protective adhesive tape includes a first insulating layer, a first conductive layer, and a second insulating layer stacked sequentially away from the substrate. The second protective adhesive tape includes a third insulating layer, a second conductive layer, and a fourth insulating layer stacked sequentially away from the substrate.

The first conductive layer is exposed to one face of the first protective adhesive tape facing the second protective adhesive tape and a region corresponding to the first lapping portion, and the second conductive layer is exposed to one face of the second protective adhesive tape facing the first protective adhesive tape and a region corresponding to the first lapping portion, so that the first conductive layer of the first protective adhesive tape is electrically connected to the second conductive layer of the second protective adhesive tape.

In a possible implementation, the substrate includes a third conductive layer, the third conductive layer includes a wire, and the wire is grounded.

The second protective adhesive tape is further electrically connected to a part of the wire.

In a possible implementation, an opening is provided in a region of one face of the second protective adhesive tape facing the substrate corresponding to the wire at a lapping position, for exposing the second conductive layer, so that the second conductive layer of the second protective adhesive tape is electrically connected to the wire.

In a possible implementation, the first insulating layer includes: a first insulating sublayer, and a first insulating adhesive layer located on a side of the first insulating sublayer away from the first conductive layer.

The first conductive layer includes: a first conductive sublayer, and a first conductive adhesive layer located on a side of the first conductive sublayer facing the first insulating layer.

The second insulating layer includes: a second insulating sublayer, and a second insulating adhesive layer located on a side of the second insulating sublayer facing the first conductive layer.

In a possible implementation, the third insulating layer includes: a third insulating sublayer, and a third insulating adhesive layer located on one side of the third insulating sublayer away from the second conductive layer.

The second conductive layer includes: a second conductive sublayer, and a second conductive adhesive layer located on a side of the second conductive sublayer facing the third insulating layer.

The fourth insulating layer includes: a fourth insulating sublayer, and a fourth insulating adhesive layer located on one side of the fourth insulating sublayer facing the second conductive layer.

In a possible implementation, the first insulating sublayer and the third insulating sublayer are made of the same material, and the first insulating adhesive layer and the third insulating adhesive layer are made of the same material.

The first conductive sublayer and the second conductive sublayer are made of the same material, and the first conductive adhesive layer and the second conductive adhesive layer are made of the same material.

The second insulating sublayer and the fourth insulating sublayer are made of the same material, and the second insulating adhesive layer and the fourth insulating adhesive layer are made of the of same material.

In a possible implementation, a width of a projection of the first lapping portion on the substrate is greater than a width of a projection of the covering portion on the substrate.

The width of the projection of the covering portion on the substrate is greater than a width of a projection of the second lapping portion on the substrate.

In a possible implementation, a length of a projection of the first lapping portion on the substrate is smaller than a length of a projection of the covering portion on the substrate.

The length of the projection of the first lapping portion on the substrate is the same as a length of a projection of the second lapping portion on the substrate.

In a possible implementation, a projection of the component group on the substrate falls within a projection of the covering portion on the substrate.

Embodiments of the present disclosure further provide a circuit board, including the first protective adhesive tape, the substrate, and the component group provided by the embodiments of the present disclosure.

Embodiments of the present disclosure further provide a display module, including a display panel, and the circuit board and the second protective adhesive tape according to the embodiments of the present disclosure.

Embodiments of the present disclosure further provide a manufacturing method for manufacturing the display module provided by the embodiments of the present disclosure. The manufacturing method includes:
providing a substrate, wherein a component group is disposed on one side of the substrate;
attaching a first protective adhesive tape to one side of the component group away from the substrate, wherein the first protective adhesive tape includes: a covering portion covering the component group, and a lapping portion extending from at least one side of the covering portion until the lapping portion comes into contact with the substrate; and
attaching a second protective adhesive tape to one side of the first protective adhesive tape away from the component group, wherein the second protective adhesive tape is attached to a periphery of the component group, and is electrically bonded to the lapping portion.

In a possible implementation, the attaching the first protective adhesive tape to one side of the substrate, includes:
providing a circuit board, wherein the component group is disposed on one side of the circuit board;
attaching the first protective adhesive tape to one side of the circuit board; and
binding the circuit board attached with the first protective adhesive tape to a display panel.

### BRIEF DESCRIPTION OF FIGURES

FIG. 1A is a top-view schematic diagram in the related art with a protective adhesive tape attached.

FIG. 1B is a schematic cross-sectional diagram along a dotted line A1B1 in FIG. 1A.

FIG. 1C is a schematic cross-sectional diagram along a dotted line C1D1 in FIG. 1A.

FIG. 2A is a top-view schematic diagram of a circuit board without a first protective adhesive tape and a second protective adhesive tape attached.

FIG. 2B is a schematic cross-sectional diagram along a dotted line A1B1 in FIG. 2A.

FIG. 3A is a top-view schematic diagram of the circuit board with the first protective adhesive tape attached.

FIG. 3B is a schematic cross-sectional diagram along a dotted line A1B1 in FIG. 3A.

Right figure of FIG. 3C is a schematic cross-sectional diagram during attaching through a transfer film along a dotted line A2B2 in FIG. 3A.

Left figure of FIG. 3C is a schematic cross-sectional diagram after the first protective adhesive tape is attached along a dotted line A2B2 in FIG. 3A.

FIG. 4A is a top-view schematic diagram of a transfer film corresponding to the second protective adhesive tape.

FIG. 4B is a top-view schematic diagram of the second protective adhesive tape.

FIG. 4C is a top-view schematic diagram after the second protective adhesive tape is attached.

FIG. 5A is a top-view schematic diagram of the circuit board attached with the first protective adhesive tape and the second protective adhesive tape.

FIG. 5B is a schematic cross-sectional diagram along a dotted line A1B1 in FIG. 5A.

FIG. 6 is a schematic diagram of a manufacturing process for a display apparatus provided by an embodiment of the present disclosure.

### DETAILED DESCRIPTION

In order to make the objectives, technical solutions and advantages of embodiments of the present disclosure clearer, the technical solutions of the embodiments of the present disclosure will be clearly and completely described below in conjunction with the accompanying drawings of the embodiments of the present disclosure. Apparently, the described embodiments are only a part of the embodiments of the present disclosure, not all of the embodiments. Based on the described embodiments of the present disclosure, all other embodiments obtained by those of ordinary skill in the art without creative work shall fall within the protection scope of the present disclosure.

Unless otherwise defined, technical or scientific terms used in the present disclosure shall have the ordinary meanings understood by those ordinarily skilled in the art to which the present disclosure pertains. The words “first”, “second” and the like used in the present disclosure do not indicate any order, quantity or importance, but are only configured to distinguish different components. The words “comprise” or “include” and the like indicate that an element or item appearing before the word covers listed elements or items appearing after the word and equivalents thereof, and does not exclude other elements or items. The terms “connecting”, “connected”, or other similar words are not limited to physical or mechanical connections, but may include electrical connections, whether direct or indirect. “Upper”, “lower”, “left”, “right” and the like are only used to represent relative position relationships, and the relative position relationships may also change accordingly after an absolute position of a described object is changed.

As used herein, “about” or “substantially the same” includes the stated value and means within an acceptable range of deviation from the value, as determined by those of ordinary skill in the art, taking into account the measurements discussed and the errors associated with the measurement of the value (i.e., the limitations of a measurement system). For example, “substantially the same” may mean that the difference relative to the stated value is within one or more standard deviations, or within ±30%, 20%, 10%, and 5%.

In the accompanying drawings, the thicknesses of layers, films, panels, regions, etc. are enlarged for clarity. Exemplary implementations are described herein with reference to cross-sectional diagrams of schematic diagrams that serve as idealized implementations. In this way, deviations from the shape of the figure as a result of, for example, manufacturing techniques and/or tolerances will be expected. Thus, implementations described herein should not be construed as being limited to the specific shape of a region as shown herein, but rather include deviations in shape caused by, for example, manufacturing. For example, regions illustrated or described as flat may typically have rough and/or non-linear characteristics. In addition, the sharp corners illustrated may be rounded. Thus, the regions shown in the figures are schematic in nature and their shapes are not intended to be the precise shapes of the illustrated regions and are not intended to limit the scope of the present claims.

In order to keep the following descriptions of the embodiments of the present disclosure clear and concise, detailed descriptions of known functions and known components are omitted.

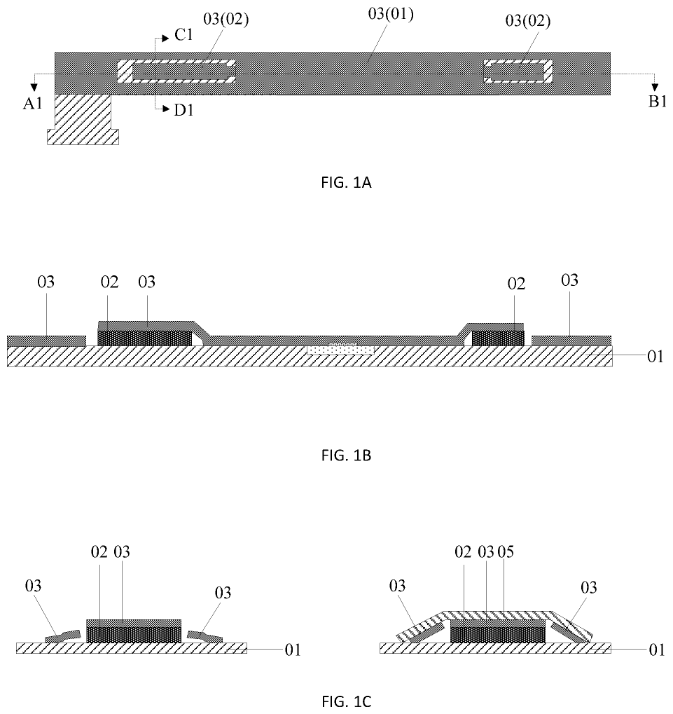

In order to improve the waterproof performance of an entire foldable product, a waterproof structure may only be designed from the inside out. Generally, a waterproof glue is dispensed around the region of a component group when a display screen is assembled to the whole product, which requires that in the display screen production process, protective adhesive tapes (EMI Tape) for electrostatic and electromagnetic protection cannot cover the periphery of the component group 02 when being attached. A glue dispensing reserved space is around the component group 02. The protective adhesive tapes 03 on the surfaces of components and a circuit board are isolated from each other, and the protective adhesive tape 03 on the surface of the component group 02 cannot be grounded. In order to realize the grounding, conventional design is as shown in FIG. 1A to FIG. 1C, where FIG. 1B is a schematic cross-sectional diagram along a dotted line A1B1 in FIG. 1A; FIG. 1C is a schematic cross-sectional diagram along a dotted line C1D1 in FIG. 1A. When the protective adhesive tape 03 is attached, integrated design is adopted, i.e., the surface of the component group 02 and the surface of the circuit board adopt a whole sheet of adhesive tape. A whole transfer film 05 is used for attachment after the circuit board is bound. The protective adhesive tape 03 on the surface of the component group 02 and the protective adhesive tape 03 on the surface of the circuit board are connected to form a whole through small regions on the side, and grounding can be realized. However, the problems of the integrated design are shown in FIG. 1C, in which the right figure of FIG. 1C is a schematic diagram during attachment through the transfer film 05, and the left figure of FIG. 1C is a schematic diagram of final attachment of the protective adhesive tape 03 after the removal of the transfer film 05. Since three sides of the protective adhesive tape 03 on the surface of the component group 02 and the protective adhesive tape 03 on the surface of the circuit board are in a fracture state, the sides of the component group 02 are in a slope type during attachment, the slope region of the protective adhesive tape 03 is narrow and long (for example, the width of 2˜3 mm, and the length of about 20 mm), and the problems of wrinkles and pseudo sticking exist necessarily during attachment, resulting in the problems of poor electromagnetic and electrostatic protection effects.

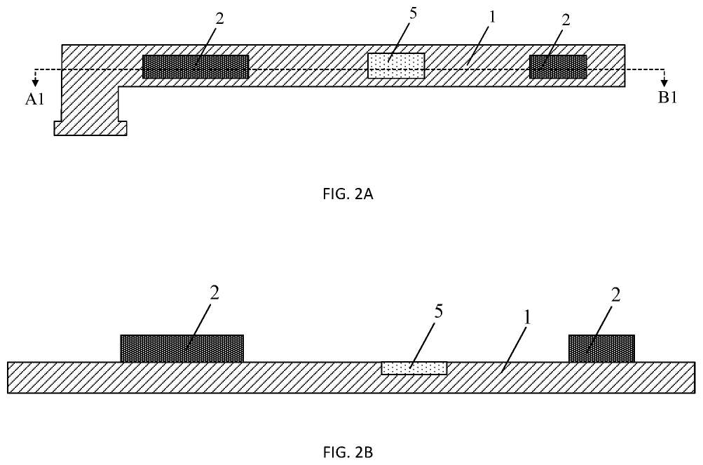

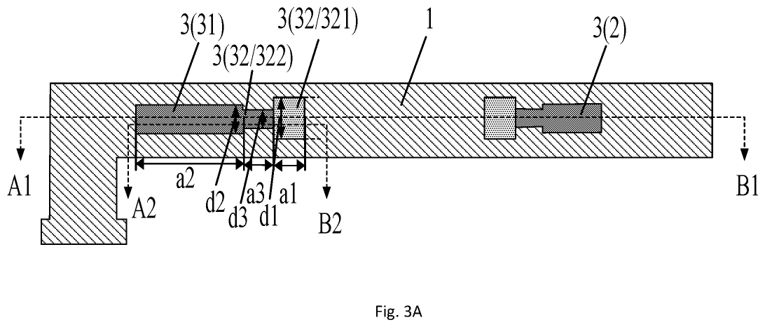

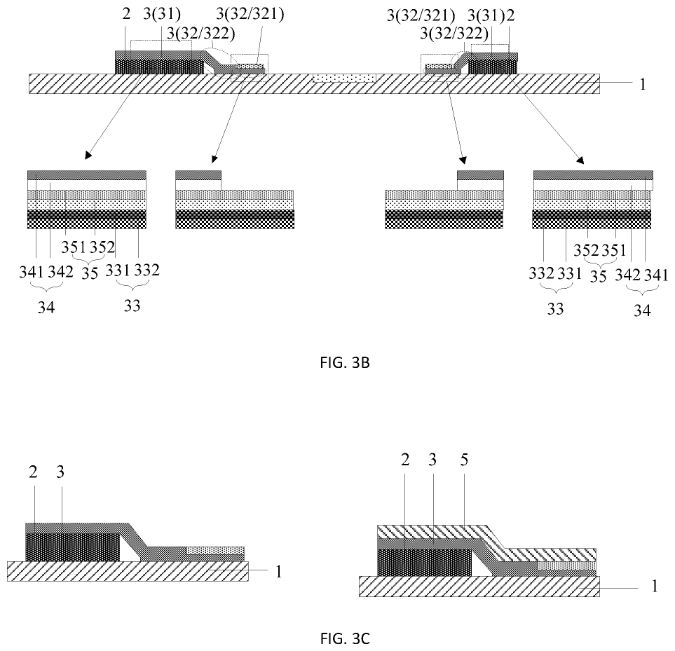

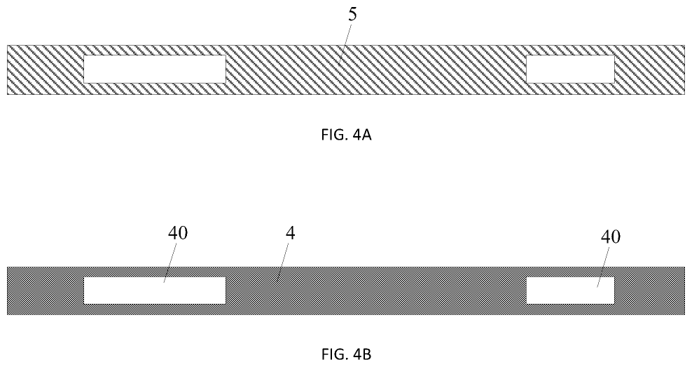

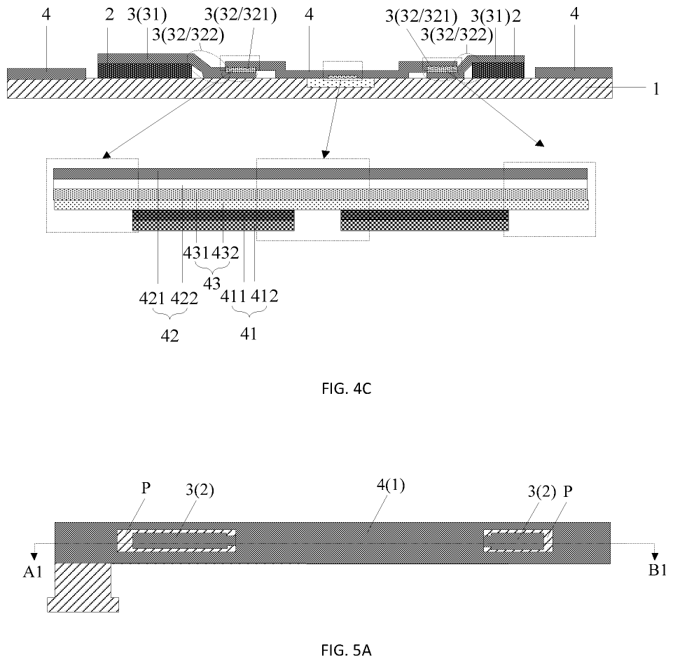

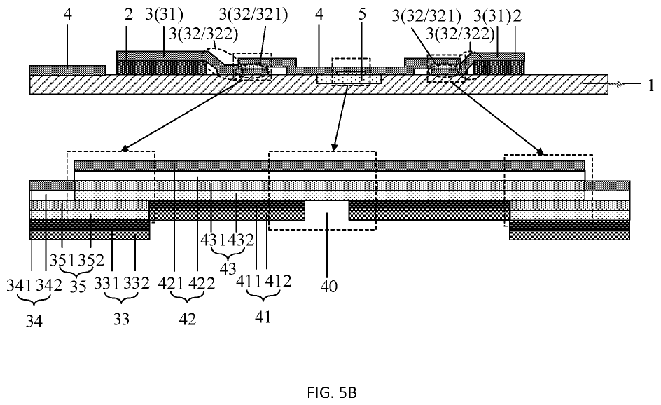

In view of this, referring to FIG. 2A to FIG. 5B, FIG. 2A is a top-view schematic diagram of a circuit board without a first protective adhesive tape and a second protective adhesive tape attached; FIG. 2B is a schematic cross-sectional diagram along a dotted line A1B1 in FIG. 2A; FIG. 3A is a top-view schematic diagram of the circuit board with the first protective adhesive tape attached; FIG. 3B is a schematic cross-sectional diagram along a dotted line A1B1 in FIG. 3A; Right figure of FIG. 3C is a schematic cross-sectional diagram during attaching through a transfer film along a dotted line A2B2 in FIG. 3A; Left figure of FIG. 3C is a schematic cross-sectional diagram after the first protective adhesive tape is attached along a dotted line A2B2 in FIG. 3A; FIG. 4A is a top-view schematic diagram of a transfer film corresponding to the second protective adhesive tape; FIG. 4B is a top-view schematic diagram of the second protective adhesive tape; FIG. 4C is a top-view schematic diagram after the second protective adhesive tape is attached; FIG. 5A is a top-view schematic diagram of the circuit board attached with the first protective adhesive tape and the second protective adhesive tape; and FIG. 5B is a schematic cross-sectional diagram along a dotted line A1B1 in FIG. 5A. Embodiments of the present disclosure provide an electronic device protection structure, including: a substrate 1, a component group 2 located on one side of the substrate 1, a first protective adhesive tape 3 located on one side of the component group 2 away from the substrate 1, and a second protective adhesive tape 4 located on one side of the first protective adhesive tape 3 away from the component group 2. For example, the component group 2 may include one or more components. The components may include, for example, a control chip IC, a capacitor C and/or a resistor R, etc.

The first protective adhesive tape 3 includes: a covering portion 31 covering the component group 2, and a lapping portion 32 extending from at least one side of the covering portion 31 until the lapping portion 32 comes into contact with substrate 1.

The second protective adhesive tape 4 is attached to a periphery of the component group 2, and is electrically connected to the lapping portion 32. In embodiments of the application, the periphery of the component group 2 may be understood as part or all of a region other than a region where the component group 2 is located.

In embodiments of the present disclosure, the electronic device protection structure includes the first protective adhesive tape 3 and the second protective adhesive tape 4 located on one side of the first protective adhesive tape 3 away from the component group 2. The first protective adhesive tape 3 includes the covering portion 31 covering the component group 2, and the lapping portion 32 extending from at least one side of the covering portion 31 until the lapping portion 32 comes into contact with the substrate 1. The second protective adhesive tape 4 is attached to the periphery of the component group 2, and is electrically connected to the lapping portion 32. That is, in the embodiments of the present disclosure, through the structural design of the lapping protective adhesive tapes, the first protective adhesive tape 3 on the surface of the component group 2 and the second protective adhesive tape 4 on the periphery of the component group 2 are separated, and then the protective adhesive tapes on two regions are connected in a lapping manner, so that the first protective adhesive tape 3 on the surface of the component group 2 can be grounded through the second protective adhesive tape 4 on the periphery of the component group 2. Since the covering portion 31 on the surface of the component group 2 and the lapping portion 32 extending out are integrated, and are separated from the second protective adhesive tape 4 on the periphery of the component group 2, wrinkles and pseudo sticking caused by integrated design during attaching are avoided, and thus the problems of poor electromagnetic and electrostatic protection effects due to wrinkles and pseudo sticking of the adhesive tape when the protective adhesive tape is attached using a related technique are also solved.

In a possible implementation, as shown in FIG. 5A, a gap P is provided between the second protective adhesive tape 4 and the component group 2. In some embodiments, the gap P may be used to set a waterproof glue for waterproofing the component group 2, i.e., by dispensing the glue to the component group 2 and the gap P on the periphery, the waterproofing of the component group 2 is strengthened, and the problem that when the circuit board is applied to a foldable display apparatus (e.g., a foldable cell phone), due to the folding characteristic, a gap exists between a whole screen and a middle frame, the waterproof function cannot be achieved through a shell, and thus the waterproof performance is not good is solved.

In a possible implementation, as shown in FIG. 3A, FIG. 3B and FIG. 5B, the lapping portion 32 includes: a first lapping portion 321 and a second lapping portion 322 connecting the first lapping portion 321 to the covering portion 31. The first lapping portion 321 is in contact with the substrate 1. The lapping portion 32 is electrically connected to the second protective adhesive tape 4 at the first lapping portion 321. In embodiments, the second lapping portion 322 is configured to connect the covering portion 31 to the first lapping portion 321, and may partially be in contact with the substrate 1, and partially inclined at an angle to the substrate 1.

In a possible implementation, as shown in FIG. 3B and FIG. 5B, lower figures of FIG. 3B are enlarged schematic diagrams of corresponding dotted boxes in the upper figure of FIG. 3B, and the lower figure of FIG. 5B shows enlarged schematic diagrams of corresponding dotted boxes in the upper figure of FIG. 5B. The first protective adhesive tape 3 includes a first insulating layer 33, a first conductive layer 35, and a second insulating layer 34 stacked sequentially away from the substrate 1. The second protective adhesive tape 4 includes a third insulating layer 41, a second conductive layer 43, and a fourth insulating layer 42 stacked sequentially away from the substrate 1. The first conductive layer 35 is exposed to one face of the first protective adhesive tape 3 facing the second protective adhesive tape 4 and a region corresponding to the first lapping portion 321, and the second conductive layer 43 is exposed to one face of the second protective adhesive tape 4 facing the first protective adhesive tape 3 and a region corresponding to the first lapping portion 321, so that the first conductive layer 35 of the first protective adhesive tape 3 is electrically connected to the second conductive layer 43 of the second protective adhesive tape 4.

In a possible implementation, as shown in FIG. 5B, the substrate 1 includes a third conductive layer. The third conductive layer includes a wire 5. The second protective adhesive tape 4 is further electrically connected to a part of the wire 5. In this way, external electrostatic or electromagnetic and other interference signals on the circuit board can be guided out. For example, the wire 5 may be made of, for example, copper.

In a possible implementation, as shown in FIG. 5B, the lapping portion 32 may extend towards one side of the circuit board with the wire 5.

In some embodiments, as shown in FIG. 5B, an opening 40 is provided in a region of one face of the second protective adhesive tape 4 facing the substrate 1 corresponding to the wire at a lapping position, for exposing the second conductive layer 43, so that the second conductive layer 43 of the second protective adhesive tape 4 is electrically connected to the wire 5.

In a possible implementation, as shown in FIG. 5B, the first insulating layer 33 includes: a first insulating sublayer 331, and a first insulating adhesive layer 332 located on one side of the first insulating sublayer 331 away from the first conductive layer 35. The first conductive layer 35 includes: a first conductive sublayer 351, and a first conductive adhesive layer 352 located on one side of the first conductive sublayer 351 facing the first insulating layer 33. The second insulating layer 34 includes: a second insulating sublayer 341, and a second insulating adhesive layer 342 located on one side of the second insulating sublayer 341 facing the first conductive layer 35.

In a possible implementation, as shown in FIG. 5B, the third insulating layer 41 includes: a third insulating sublayer 411, and a third insulating adhesive layer 412 located on one side of the third insulating sublayer 411 away from the second conductive layer 43. The second conductive layer 43 includes: a second conductive sublayer 431, and a second conductive adhesive layer 432 located on one side of the second conductive sublayer 431 facing the third insulating layer 41. The fourth insulating layer 42 includes: a fourth insulating sublayer 421, and a fourth insulating adhesive layer 422 located on one side of the fourth insulating sublayer 421 facing the second conductive layer 43.

In a possible implementation, as shown in FIG. 5B, the first insulating sublayer 331 and the third insulating sublayer 411 are made of the same material, and the first insulating adhesive layer 332 and the third insulating adhesive layer 412 are made of the same material. In some embodiments, the first insulating sublayer 331 and the third insulating sublayer 411 are, for example, both made of polyethylene terephthalate (PET). In some embodiments, the first insulating adhesive layer 332 and the third insulating adhesive layer 412 are both made of pressure sensitive adhesives (PSA).

The first conductive sublayer 351 and the second conductive sublayer 431 are made of the same material, and the first conductive adhesive layer 352 and the second conductive adhesive layer 432 are made of the same material. In some embodiments, the first conductive adhesive layer 352 and the second conductive adhesive layer 432, for example, may be conductive fabrics, for another example, may be copper layers, and for yet another example, may be electrostatic spinning fibers. In some embodiments, the first conductive adhesive layer 352 and the second conductive adhesive layer 432, for example, may be pressure sensitive adhesives (PSA).

The second insulating sublayer 341 and the fourth insulating sublayer 421 are made of the same material, and the second insulating adhesive layer 342 and the fourth insulating adhesive layer 422 are made of the of same material. In some embodiments, the second insulating sublayer 341 and the fourth insulating sublayer 421, for example, may be Mylar adhesive layers; and the second insulating adhesive layer 342 and the fourth insulating adhesive layer 422, for example, may be pressure sensitive adhesives (PSA).

In a possible implementation, as shown in FIG. 3A, in a direction perpendicular to a direction where the covering portion 31 points to the lapping portion 32, a width d1 of a projection of the first lapping portion 321 on the substrate 1 is greater than a width d2 of a projection of the covering portion 31 on the substrate 1. In the direction perpendicular to a direction where the covering portion 31 points to the lapping portion 32, the width d2 of the projection of the covering portion 31 on the substrate 1 is greater than a width d3 of a projection of the second lapping portion 322 on the substrate 1.

In a possible implementation, as shown in FIG. 3A, in the direction where the covering portion 31 points to the lapping portion 32, a length a1 of the projection of the first lapping portion 321 on the substrate 1 is smaller than a length a2 of the projection of the covering portion 31 on the substrate 1. In the direction where the covering portion 31 points to the lapping portion 32, the length a1 of the projection of the first lapping portion 321 on the substrate 1 is equal to a length a3 of the projection of the second lapping portion 322 on the substrate 1.

In a possible implementation, as shown in FIG. 2A and FIG. 3A, an orthographic projection of the component group 2 on the substrate 1 falls within an orthographic projection of the covering portion 31 on the substrate 1. In some embodiments, the orthographic projection of the covering portion 31 on the substrate 1 and the orthographic projection of the component group 2 on the substrate 1 may coincide mutually.

Based on the same inventive concept, embodiments of the present disclosure further provide a circuit board, including the first protective adhesive tape, the substrate, and the component group provided by the embodiments of the present disclosure.

In a possible implementation, the circuit board is a flexible printed circuit board (FPC).

Based on the same inventive concept, embodiments of the present disclosure further provide a display module, including a display panel, and the circuit board and the second protective adhesive tape provided by the embodiments of the present disclosure. In some embodiments, the display module of the embodiments of the present disclosure may be a foldable display apparatus, for example, a foldable cell phone, a foldable tablet computer, a foldable television, a foldable display, a foldable laptop, a foldable digital photo frame, a foldable navigator and any product or component with a display function. Other essential components of the display apparatus shall be understood by those of ordinary skill in the art, and are omitted herein and also shall not become a restriction to the present disclosure.

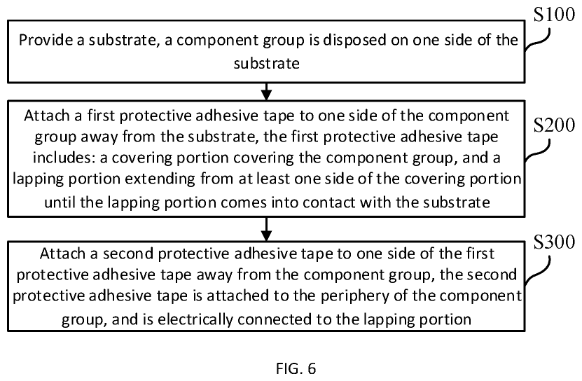

Based on the same inventive concept, embodiments of the present disclosure further provide a manufacturing method for manufacturing the display module provided by the embodiments of the present disclosure. Referring to FIG. 6, the manufacturing method includes the following.

Step S100, a substrate is provided. A component group is disposed on one side of the substrate.

Step S200, a first protective adhesive tape is attached to one side of the component group away from the substrate. The first protective adhesive tape includes: a covering portion covering the component group, and a lapping portion extending from at least one side of the covering portion until the lapping portion comes into contact with the substrate.

Step S300, a second protective adhesive tape is attached to one side of the first protective adhesive tape away from the component group. The second protective adhesive tape is attached to a periphery of the component group, and is electrically connected to the lapping portion.

In a possible implementation, the step S200 of attaching the first protective adhesive tape to one side of the component group away from substrate includes the following.

Step S201, a circuit board is provided. The component group is disposed on one side of the circuit board.

Step S202, the first protective adhesive tape is attached to one side of the circuit board.

Step S203, the circuit board attached with the first protective adhesive tape is bound to a display panel.

In the embodiments of the present disclosure, the first protective adhesive tape may be attached as soon as a circuit board supplier has finished fabricating the circuit board, so that the function of electrostatic protection is achieved when the circuit board is monolithic, and the process steps of the module factory are not increased.

The embodiments of the present disclosure have the following beneficial effects: in the embodiments of the present disclosure, the electronic device protection structure includes the first protective adhesive tape 3 and the second protective adhesive tape 4 located on one side of the first protective adhesive tape 3 away from the component group 2; the first protective adhesive tape 3 includes the covering portion 31 covering the component group 2, and the lapping portion 32 extending from at least one side of the covering portion 31 until the lapping portion 32 comes into contact with the substrate 1; and the second protective adhesive tape 4 is attached to the periphery of the component group 2, and is electrically connected to the lapping portion 32. That is, in the embodiments of the present disclosure, through the structural design of the lapping protective adhesive tapes, the first protective adhesive tape 3 on the surface of the component group 2 and the second protective adhesive tape 4 on the periphery of the component group 2 are separated, and then the protective adhesive tapes on two regions are connected in a lapping manner, so that the first protective adhesive tape 3 on the surface of the component group 2 can be grounded through the second protective adhesive tape 4 on the periphery of the component group 2. Since the covering portion 31 on the surface of the component group 2 and the lapping portion 32 extending out are integrated, but are separated from the second protective adhesive tape 4 on the periphery of the component group 2, wrinkles and pseudo sticking caused by integrated design during attaching are avoided, and thus the problems of poor electromagnetic and electrostatic protection effects due to wrinkles and pseudo sticking of the adhesive tape when the protective adhesive tape is attached to the circuit board using a related technique are also solved.

Obviously, those skilled in the art can make various modifications and variations to the present disclosure without departing from the spirit and scope of the present disclosure. In this way, if these modifications and variations of the present disclosure fall within the scope of the claims of the present disclosure and equivalent technologies thereof, the present disclosure is also intended to include these modifications and variations.

1. An electronic device protection structure, comprising:
a substrate,
a component group on a side of the substrate,
a first protective adhesive tape on a side of the component group away from the substrate, and
a second protective adhesive tape on a side of the first protective adhesive tape away from the component group;
wherein the first protective adhesive tape comprises:
a covering portion covering the component group, and
a lapping portion extending from at least one side of the covering portion until the lapping portion comes into contact with the substrate; and
the second protective adhesive tape is attached to a periphery of the component group, and is electrically connected to the lapping portion.

2. The electronic device protection structure according to claim 1, wherein a gap is provided between the second protective adhesive tape and the component group.

3. The electronic device protection structure according to claim 1, wherein the lapping portion comprises:
a first lapping portion, and
a second lapping portion connecting the first lapping portion to the covering portion;
wherein the first lapping portion is in contact with the substrate, and the lapping portion is electrically connected to the second protective adhesive tape at the first lapping portion.

4. The electronic device protection structure according to claim 3, wherein the first protective adhesive tape comprises a first insulating layer, a first conductive layer, and a second insulating layer stacked sequentially away from the substrate; the second protective adhesive tape comprises a third insulating layer, a second conductive layer, and a fourth insulating layer stacked sequentially away from the substrate; and
the first conductive layer is exposed to one face of the first protective adhesive tape facing the second protective adhesive tape and a region corresponding to the first lapping portion, and the second conductive layer is exposed to one face of the second protective adhesive tape facing the first protective adhesive tape and a region corresponding to the first lapping portion, so that the first conductive layer of the first protective adhesive tape is electrically connected to the second conductive layer of the second protective adhesive tape.

5. The electronic device protection structure according to claim 4, wherein the substrate comprises a third conductive layer, the third conductive layer comprises a wire, and the wire is grounded; and
the second protective adhesive tape is further electrically connected to a part of the wire.

6. The electronic device protection structure according to claim 5, wherein an opening is provided in a region of one face of the second protective adhesive tape facing the substrate corresponding to the wire at a lapping position, for exposing the second conductive layer, so that the second conductive layer of the second protective adhesive tape is electrically connected to the wire.

7. The electronic device protection structure according to claim 4, wherein the first insulating layer comprises a first insulating sublayer, and a first insulating adhesive layer on a side of the first insulating sublayer away from the first conductive layer;
the first conductive layer comprises a first conductive sublayer, and a first conductive adhesive layer on a side of the first conductive sublayer facing the first insulating layer; and
the second insulating layer comprises a second insulating sublayer, and a second insulating adhesive layer on a side of the second insulating sublayer facing the first conductive layer.

8. The electronic device protection structure according to claim 7, wherein the third insulating layer comprises a third insulating sublayer, and a third insulating adhesive layer on a side of the third insulating sublayer away from the second conductive layer;
the second conductive layer comprises a second conductive sublayer, and a second conductive adhesive layer on a side of the second conductive sublayer facing the third insulating layer; and
the fourth insulating layer comprises a fourth insulating sublayer, and a fourth insulating adhesive layer on a side of the fourth insulating sublayer facing the second conductive layer.

9. The electronic device protection structure according to claim 8, wherein the first insulating sublayer and the third insulating sublayer are made of a same material, and the first insulating adhesive layer and the third insulating adhesive layer are made of a same material;
the first conductive sublayer and the second conductive sublayer are made of a same material, and the first conductive adhesive layer and the second conductive adhesive layer are made of a same material; and
the second insulating sublayer and the fourth insulating sublayer are made of a same material, and the second insulating adhesive layer and the fourth insulating adhesive layer are made of a same material.

10. The electronic device protection structure according to claim 3, wherein a width of a projection of the first lapping portion on the substrate is greater than a width of a projection of the covering portion on the substrate; and
the width of the projection of the covering portion on the substrate is greater than a width of a projection of the second lapping portion on the substrate.

11. The electronic device protection structure according to claim 3, wherein a length of a projection of the first lapping portion on the substrate is smaller than a length of a projection of the covering portion on the substrate; and
the length of the projection of the first lapping portion on the substrate is same as a length of a projection of the second lapping portion on the substrate.

12. The electronic device protection structure according to claim 3, wherein a projection of the component group on the substrate falls within a projection of the covering portion on the substrate.

13. A circuit board, comprising the first protective adhesive tape, the substrate and the component group according to claim 1.

14. A display module, comprising a display panel, and the circuit board and the second protective adhesive tape according to claim 13.

15. A manufacturing method for manufacturing the display module according to claim 14, comprising:
providing the substrate, wherein the component group is disposed on the side of the substrate;
attaching the first protective adhesive tape to the side of the component group away from the substrate, wherein the first protective adhesive tape comprises the covering portion covering the component group, and the lapping portion extending from at least one side of the covering portion until the lapping portion comes into contact with the substrate; and
attaching the second protective adhesive tape to the side of the first protective adhesive tape away from the component group, wherein the second protective adhesive tape is attached to the periphery of the component group, and is electrically connected to the lapping portion.

16. The manufacturing method according to claim 15, wherein said attaching the first protective adhesive tape to the side of the substrate, comprises:
providing a circuit board, wherein the component group is disposed on a side of the circuit board;
attaching the first protective adhesive tape to a side of the circuit board; and
binding the circuit board attached with the first protective adhesive tape to the display panel.
